(19) United States
(12) Patent Application Publication
(10) Pub. No.: US 2024/0111924 A1
(43) Pub. Date: Apr. 4, 2024

(54) Distributed Invasive Species Tracking Network

(71) Applicant: Nathan Easaw Elias, Austin, TX (US)

(72) Inventor: Nathan Easaw Elias, Austin, TX (US)

(21) Appl. No.: 18/479,810

(22) Filed: Oct. 2, 2023

Related U.S. Application Data
(60) Provisional application No. 63/412,416, filed on Oct. 1, 2022.

(51) Int. Cl. G06F 30/20; G06N 3/0464

(52) U.S. Cl. CPC G06F 30/20; G06N 3/0464

(57) ABSTRACT

A machine learning algorithm and database is presented herein which can be trained on data of one or more species, and using both known and assumed parameters as well as real-world data, can be trained to predict the movement, expansion, and retraction of invasive species over time. This data may be dynamically updated based on additional real-world data gathered as time passes. In the preferred embodiment, the machine learning algorithm further comprises machine learning algorithms trained to accurately determine the species of animals captured in imaging devices such as cell phone cameras in order to update the predictive algorithms. Yet further innovations may artificially expand limited datasets in order to better train the algorithms.

### CROSS-REFERENCE TO RELATED APPLICATIONS

The present application claims the benefit of the prior-filed provisional application bearing the application No. 63/412,416, filed Oct. 1, 2022.

### PRIOR ART

There have been previous attempts at creating mobile applications to mitigate invasive species growth, such as EDDMapS and iMaplnvasives. However, these applications only plot reported invasive species occurrences, but among other limitations these do not predict future growth or automatically identify invasive species. The proposed novel method will predict the spread of invasive species into suitable environments using LSTM geospatial models.

Certain algorithms and techniques, such as Seasonal AutoRegressive Integrated Moving Averages with eXogenous regressors (SARIMAX) for calculating moving averages, and Hierarchical Density-Based Geospatial Clustering (HDBSCAN) for tracking the movement of clusters of data, are known in the art of prediction and tracking of data sets and are utilized herein as one preferred method for development and prediction of data. However, their use in the art of invasive species tracking, detection, and control has not previously been employed with significant success, as alone or in conjunction they are not sufficiently accurate for the purpose of invasive species tracking and prediction, especially given the small or poor-quality datasets available for training with many invasive species.

In all embodiments claimed, the present invention further enhances the precision and accuracy of Network predictions with real-time tracking of weather, climate, location and environment, and with real-world tracking of predation and competition ranges processed through the Network's particular long short-term memory algorithms and machine learning processes.

Further, in its preferred embodiment, the present invention will allow for automated detection and reporting of an invasive species through Convolutional Neural Networks (CNNs) or analogous systems. Automated visual recognition of invasive species has been insufficiently developed as there are too few available images of sufficient quality to properly train a machine learning algorithm to recognize such species on sight. The novel method presented herein for the preferred embodiment overcomes this long-felt need through a technique of image augmentation disclosed herein.

### BACKGROUND OF THE INVENTION

In the U.S. alone, invasive species cause major environmental damage and losses adding up to almost $120 Billion annually. Globally, the cost has been estimated at $1.4 Trillion. As invasive foreign species continue to spread globally, more than 40% of species on the Threatened or Endangered species lists are at immediate risk. Invasive species can pose a risk of severe ecological disruption as they may find no natural predators or rivals in their new environment. This is true of pathogens, fungi, plants, insects, and animals alike. The risk to global biodiversity is not merely abstract, as the proliferation of an invasive species outcompeting a native species in a given area can devastate the local ecology. Such imbalances may result in degraded quality of land and soil, higher pest control costs, food chain disruption, and in some instances even increased wildfires and flooding. The need for an ability to identify, recognize, and track invasive species and their movements has been long felt in the scientific community. Early detection and rapid response remains the most effective way to deal with the incursions of new invasive species to an area.

While proliferation of these invasive species is a clear and present crisis, the current proliferation of “smart” technology and neural-network systems presents the chance for a solution. The miniaturization and near-universal adoption of consumer smart devices, and drone technology have placed vast swaths of the planet within the scope of easy and low-cost surveillance, while widespread cellular coverage and wireless internet access have made it possible to centralize information gathering at the speed of electronic transmission.

The more recent advent of neural-net and machine learning technology forms the last piece necessary to “crowdsource” the gathering of invasive species data, sort through the data, reduce or eliminate bad data, and produce predictive models based on such constantly-updated new data on a scale wide enough to be useful, while centralizing the collection and display of such data. Without such crowdsourcing, mass gathering of data is not feasible in the real world; even the wealthiest universities or regulatory agencies simply could not afford to keep hundreds of people in the wild with cameras hoping to spot, identify, and record the location and movements of these invasive creatures.

Such machine learning technology can under optimal conditions be trained to recognize various plant, animal, pathogen, insect, and fungus species from given inputs, such as photographs; this is desirable as a replacement for user-provided identification. Indeed, crowdsourcing such data would be worthless without such machine learning algorithms because ordinary people cannot easily distinguish one species from another; even experts may be unable to identify a given species accurately without substantial time and clear, high-quality inputs such as high-resolution photographs. The data from user-identified sightings or discoveries of the presence of invasive species in the wild would be impossible to rely upon due to the unreliability of laypeople. Further, users could easily suffer from “target fixation” in photographs with two or more species. For example, a photograph of an invasive species of bird may contain an extremely high-quality, identifiable image of that bird, drawing the attention of a human user away from an unnoticed, partially-obscured or out-of-focus image of an invasive plant species in another portion of the photograph.

While the pieces are in place for the system described, significant hurdles remain to be addressed. First and foremost is the problem of filtering bad data from good data. Crowdsourced data from mobile devices, trail cameras, drones, and publicly-available research data produces new data of widely variable quality. Photographs by untrained photographers or low-quality trail cameras may produce bad photographs, particularly in low-light or rainy conditions as found in nature. Even the best photographs may still yield lower-quality data to the extent that the subject species is obscured by foliage, terrain, or other objects, or to the extent the subject species is an unusual color due to natural variation or disease. Data may be insufficient to properly train neural net learning systems to recognize certain species from photographs or other input data, especially when the quality or resolution of such data is low or the species is difficult to distinguish visually from others of its genus or family. Subsequent data may contradict predictions, requiring a model to be amended. Updating the training of a neural net with bad data may cause the system to become worse at its designated task. Any solution to such problems requiring excessive human intervention reduces or even nullifies the advantage of automation in the first place.

The essential problem lies in the necessity of training a machine learning algorithm to extract good data from inputs which range in quality from very good to very poor. Real-world conditions may necessitate that input is gathered in very poor quality or resolution. To train a machine learning algorithm to extract good data from such inputs, the machine must be trained on bad data. The “best” bad data comes from real-world conditions; it follows that the best way to improve the robustness of a data-recognition algorithm, particularly a visual image recognition algorithm, is with real-world data. However, training an algorithm on bad data risks training the algorithm such that it is biased toward bad data and away from optimally recognizing such data. Excessive requirements for human intervention after initial training will reduce or eliminate the benefits of using machine learning algorithms entirely. But without such data, the accuracy of machine predictions is limited.

Previous inventions in the art have thus been constrained to limited use of machine learning. Fox 1, U.S. Pat. No. 11,074,447, discloses use of artificial intelligence to enhance aerial photographs and identify plant growth, but relies on the comparison of multiple images of the same terrain taken during multiple flights over an area from an aerial drone. This system is difficult and expensive to scale, and effectively impossible to expand to the level of true crowdsourcing. Further, Fox discloses a method of training the machine learning model using images annotated by the algorithm itself based on repeated images of the same terrain over time; this method is further limited as it does not disclose any means of improving the detection algorithm for identification of other examples of the same species, nor of identifying animals in any respect.

Walters, U.S. Pat. No. 10,884,894, discloses a method of training an algorithm and recursively training said algorithm on its own synthetic data; however, this disclosure is limited to training on entirely-new synthetic data and original data only. This method does not disclose methods for the improvement of existing images as usable, enhanced training data, nor does the disclosure in Walters enable the intermingling of single, intrinsically-mixed data sets such as color-enhanced or AI-focused images rather than entirely novel machine-generated images, limiting such recursive training for the identification of objects in photographs or similar datasets. Producing poorer-quality datasets would in fact run counter to the disclosed method of this invention.

Moyal, U.S. Pat. No. 11,743,552, disclosed a method of improving the resolution of streaming video using said generative adversarial network However, the method disclosed is limited to altering such video to more closely resemble an optimized video from training data in order to produce a more engaging video stream; the method does not disclose, and indeed teaches away from, development or enhancement of images in which objects are less clear and less easily identified by a viewer. Indeed, training of this system and others like it on poor-quality images would run counter to the method, as it would reduce image quality.

In short, the field of invasive species tracking indicates a long-felt need for an upscaled, crowdsource-enabled means of collecting data en masse, but has been constrained by lack of systems enabling such collection in useful form. The prior art in the field of training image recognition and image enhancement algorithms indicates a need for an improved method of training in which such algorithms may better extract useful data from low quality images or other inputs, but to date training has focused on image enhancement. A need exists for a system to collate crowdsourced and other mass-collected data in sub-optimal conditions in order to fill the need for a predictive model of the movement and expansion of invasive species at scale.

### SUMMARY OF THE INVENTION

The present invention proposes a novel solution to the problem of invasive species movements through the use of machine learning and prediction. Machine learning can be trained on a given species' known instances of appearance in an environment as well as its known parameters of growth to produce a predictive model. Rather than traditional methods of obtaining data tracking invasive species such as compiling reported sightings or tagging captured animals, the present invention takes advantage of the already-existing network of distributed computing, including preferably mobile devices, cloud servers, and related hardware, using these as a data entry and storage network, preferably via an app interfacing with a centralized database; however, any distributed network of devices comprising at least a plurality of processors, memories, output devices, and input devices will suffice. The Network can accept data from any users through any applicable input device, including a mobile device, updating its own dataset and training data accordingly with real instances of detected invasive species.

For the purposes of this document, “machine learning” should be understood to comprise both its conventional meaning in software development as well as any of neural networks, attention network models, genetic algorithms, deep learning, decision trees, case-based reasoning, fuzzy logic, artificial intelligence, any of a generative adversarial model (GAN), a recurrent neural network (RNN) model, a long short-term memory (LSTM) model, a random forest model, a convolutional neural network (CNN) model, an RNN-CNN model, a temporal-CNN model, a support vector machine (SVM) model, a natural-language model, and/or another machine-learning model, whether supervised, partially supervised, or unsupervised, and whether including an ensemble model or other parallelized machine learning through processors such as graphical processing units (GPUs) or central processing units (CPUs). Any such term may be named with specificity, but otherwise the term “machine learning algorithm” or “MAL” will be used. A computer may include any device with electronic data processing or machine-readable instruction-reading capabilities known in the art; this may include but is not limited to desktop and laptop computers, mainframe computers, smart devices such as smart phones, tablets, personal digital assistants (PDAs), field-programmable gate array (FPGA) based devices, or application-specific integrated circuit (ASIC) based devices; cloud-based or network-based versions of each such computing device are further intended to be included herein.

In this model, “training” refers to the process of exposing the machine learning algorithm to sets of related data until the machine learns to recognize selected items within the data well enough to identify or generate new examples of the selected data. The most basic method to this process is known in the art, and so will be recounted only in the briefest way herein. As an example, a machine learning algorithm being trained to recognize images of cats may be made to process to thousands of images of cats until it learns to recognize new cats in new images; the algorithm gains enough data matching the basic shape, color, and other qualities of the image of a cat as distinct from the qualities of the surrounding environment in each photograph that later instances of such qualities can be quickly and accurately identified. Such basic methods have their pitfalls unless the data is chosen with great care. A machine exposed to many pictures of black cats and few pictures of orange cats may have difficulty recognizing orange cats as cats, or may falsely identify black dogs as cats. Such a case might be ameliorated by exposing the machine learning algorithm to images of dogs and cats, or of a broader variety of cats, training it to recognize the difference with a greater degree of precision.

Low-quality images exacerbate the problem. Data scientists practicing the art of training such machine learning algorithms are continuously developing new ways to reduce the number of Type I and Type II errors (that is, false positives and false negatives), but the process is labor-intensive when supervised. If there is too much data in set, or if much of the dataset is of poor quality for training purposes, the data scientists may not have the manpower to manually supervise machine learning in a reasonable amount of time. If there is too little data of high training quality, the algorithm may remain prone to errors as certain weighted recognition values are not trained sufficiently high or low. In part, the present invention includes a technique to artificially broaden a limited dataset in a novel way to enhance the training process and reduce the sorts of errors that arise in undertrained algorithms.

Parameters for a moving average of each invasive species' movement, growth, and reduction over time may be adjusted as a machine learning algorithm is updated to comprise new instances of detected invasive species. The machine learning algorithm can then generate predictions from this data. Predictions are updated over time as real data is added. The multiplicative effect of this distributed network offers a vast advantage over traditional data entry, as data may be added by any helpful individual with a mobile device connected to the Network rather than official reports only. Further inputs may be obtained from trail cameras, drones, and other reports. The machine learning algorithm is able to extract useful data from these inputs at scale, even when such data is obtained or provided by a layperson rather than an expert, as the machine learning algorithm is able to make its own determination of the species indicated in the data rather than relying entirely on user reports. The ability to obtain reliable data from effectively unlimited numbers of lay contributors at a usable speed in this manner is thus enabled, where previously such participation would be impractical due to the need for mass verification of data, or even counterproductive due to introduction of bad data into the dataset.

To further augment this multiplicative benefit, the machine learning algorithm can use location data and photographs from these mobile devices on the Network to obtain more accurate information about instances of invasive species, removing the effects of human error and inaccuracy by automating the process of recognition and reporting. As many invasive species possess insufficiently large datasets to train existing machine learning algorithms, the present invention further incorporates novel training techniques to overcome shortages of training data, overcoming another problem known in the art.

### BRIEF DESCRIPTION OF DRAWINGS

FIG. 1 is a block diagram of the iterative process of training the machine learning algorithm according to genuine and synthetic images.

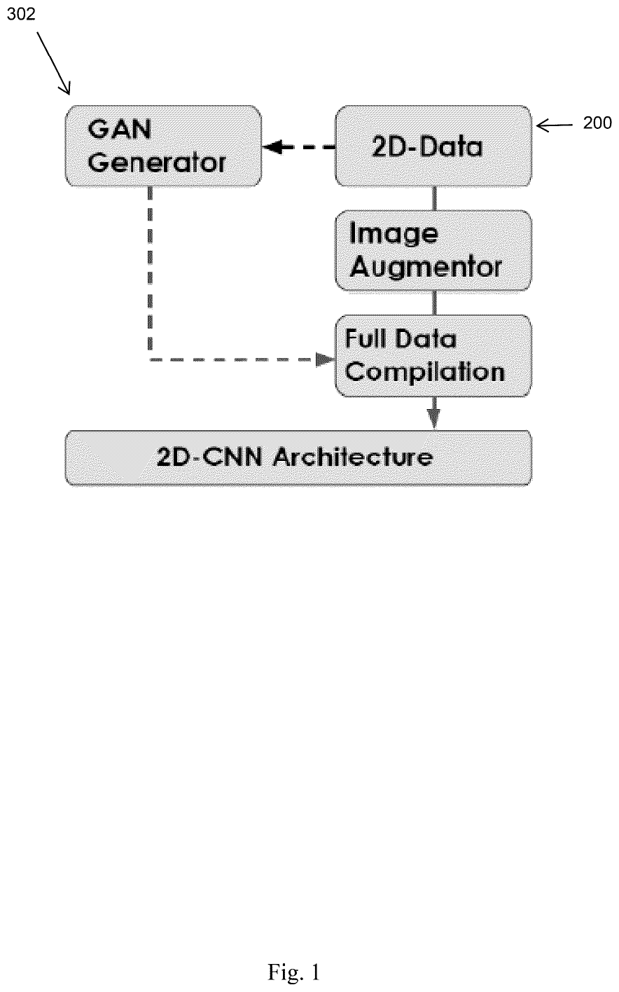

FIG. 2 is a simplified block diagram and flowchart of the preferred embodiment of the invention, in which the model processes data from and exports predictions to a mobile app and other remote input devices.

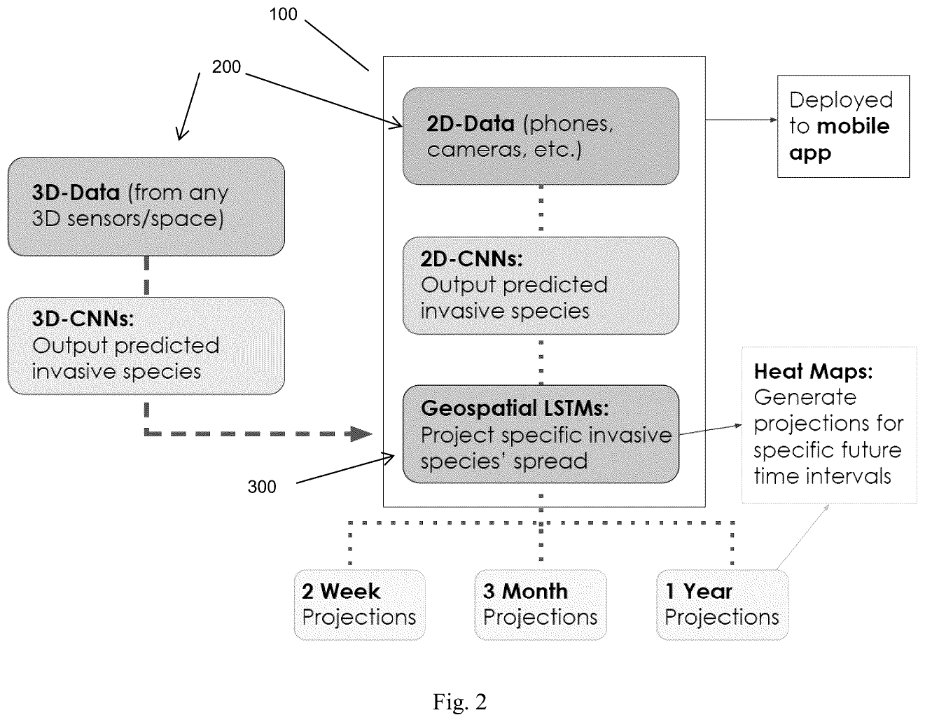

FIG. 3 is a block diagram of the prediction model.

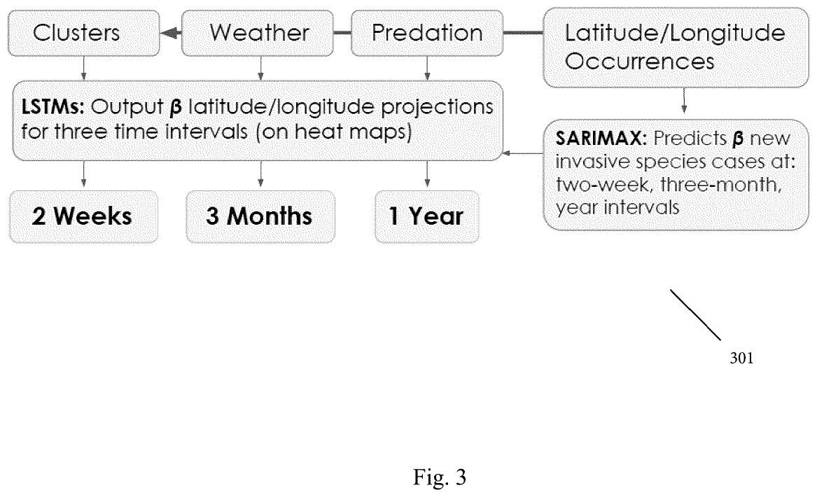

### DETAILED DESCRIPTION OF THE INVENTION

The Network as described herein is a tool, preferably a software tool, configured to detect and identify invasive species, and further configured to predict the expansion of instances of said invasive species; a method is further disclosed for use of the Network. The Network is further configured to enhance the accuracy of detection and identification by means of a novel recursive image alteration and training loop disclosed herein.

The invention comprises at a minimum at least one computing device 100, itself comprising at least one memory configured to store a plurality of dynamic species models 300, at least one processor communicatively coupled to the at least one memory, an at least one output device communicatively coupled to the at least one processor, and at least one input device configured to receive input, each of said at least one input devices communicatively coupled to the at least one processor. The at least one memory comprise at least a short term electronic memory and a long term electronic memory; each of said short term and long term electronic memories may be further subdivided into smaller units acting independently as, respectively, a short term electronic memory or a long-term electronic memory.

At least one of the at least one memories will be configured to store one or more dynamic species models 300, each dynamic species model 300 comprising a machine learning algorithm and an updateable species dataset. Each machine learning model further comprises an at least one generative adversarial network 302, a geospatial growth prediction algorithm 301, and an identifying machine learning algorithm. Each updateable species dataset further comprises at least one instance of one indexed species, and at least one corresponding indexed species datum 200. Each indexed species datum 200 comprises information about the indexed species, which may be in the form of an image, a video, time and location data, known or estimated population data, known reproduction rate data, auditory data, and/or other dataThe updateable species dataset is configured to receive additional instances of the indexed species. The machine learning algorithm is trained to identify and generate instances of indexed species data.

The dynamic species model 300 is configured to generate a prediction of the movement and growth of the respective indexed species according to the information in the corresponding updateable species dataset. The at least one output device is configured to display the generated prediction.

The input device is configured to provide new instances of data, each a new datum. The machine learning algorithm processes the new datum in comparison to the dynamic species model 300. The new datum is compared to the dynamic species models 300 until the presence of any indexed species can be identified as an indexed invasive species, or as a native species or an unknown species. New instances of indexed species data are stored on the memory within the corresponding updateable species dataset.

The machine learning algorithm is further configured to generate new instances of synthetic data, each a synthetic datum. The machine learning algorithm is configured to be further trained on these instances of synthetic data and on new data.

In the preferred embodiment, the present invention is embodied in a Network, comprising an arbitrary number of independent computing devices 100 communicatively coupled to the Network, preferably via the Internet. Data from any number of said independent computing devices 100 is stored in the memory as described. Any independent computing device 100 in the Network may serve as an input device, processor, memory, or output device for the invention.

In the most basic form of the present invention, an instance of indexed species is detected, the detected instance of the indexed species is recorded into a working memory connected to the Network via an input device, the indexed species within the recorded instance is identified by a machine learning algorithm, the recorded instance is appended to an indexed dataset, and the geospatial growth prediction algorithm 301 models and develops geospatial predictions of present and future spread of the indexed species from one or more of said indexed datasets. In the instance of visual data, the Network further generates one or more altered artificial copies of the recorded instance altered by means of an image-enhancement algorithm to generate similar but not identical artificial images of higher or lower quality, then trains the machine learning algorithm according to these artificial images as well as the instance of visual data in order to improve the accuracy of the machine learning algorithm. In the instance of audio or other data, the Network may in other embodiments generate one or more altered artificial instances of audio or other data, respectively, by means of an audio- or other data-enhancement algorithm to generate similar but not identical artificial instances of audio or other data, then trains the machine learning algorithm according to these artificial instances of audio or other data as well as the instance of audio or other data in order to improve the accuracy of the machine learning algorithm. In this way the Network can be quickly trained even using very limited data sets, and further improves itself over time.

After several iterations of the training as disclosed herein, CNNs trained in this method have experimentally achieved test accuracies in excess of 97% against the original test image sets of invasive species. Existing models known to the inventor prior to this method achieve accuracy no higher than 67.74%. This amount to an improvement of approximately thirty percentage points. This represents a substantial and unexpectedly large leap in such accuracy; it is this surprising leap in accuracy of automated identification which makes feasible the novel crowdsourcing of information provided by laypeople. Further, there is at present no indication that 97% represents the maximum possible accuracy of this model, which may continue to grow as the invention improves.

The input devices presented herein are for illustrative purposes only. The present invention does not disclose a novel input device or hardware, nor is the present invention limited to currently-existing input devices. Other usable input devices may be apparent to one skilled in the art in light of this disclosure; embodiments of the devices incorporating the use of such usable input devices are intended to be claimed herein.

In the preferred embodiment, the Network comprises as many input devices as can be sourced, including but not limited to visual input devices and audio input devices. One preferred visual input device comprises a camera of the sort commonly found on a mobile device; data obtained from such input devices further preferentially comprises metadata, including location data as is commonly appended to such by commercially-available mobile devices. Other preferred visual input device comprise trail cameras, drone cameras, dash cameras, and other cameras integrated with internet, wireless, or cellular access which may be found in a given environment. Yet further preferred input devices comprise trail microphones. Further still, input may be entered electronically by observers; preferably, data entered without images or other sensory data is entered by experts in the study of the identified species, and such data preferably further comprises metadata identifying the observer and his or her credentials.

Data may be provided to the Network by means commonly known in the art, preferably via use of the Internet or world wide web. Data may further be entered manually. Data may yet further be obtained by “scraping” an external database.

“Training” a machine learning algorithm as disclosed herein comprises an enhancement of the general training means and methods known in the prior art with the steps set forth below. Training the machine learning algorithm is generally known to require a dataset of training data, in this case, images of an indexed species. Insufficient training data results in poor training, a problem well-known in the art; the present invention discloses a novel means of enhancing inadequate datasets for training purposes.

Updating and tracking examples of invasive species from multiple sources, both official and crowdsourced, is made possible at this scale through the use of internet-connected computer databases. Good training necessarily must include poor-quality images and other data; the machine learning algorithm of the present invention must be trained to identify instances of an indexed species from poor-quality images and other data from the indexed species in the wild. Using actual images and other data taken in the wild as training data provides the best example of such low-quality inputs. A well-known problem of machine learning algorithms is errors arising from training on poor-quality data, producing downstream bad results. This problem is mitigated by the image enhancement training technique set herein. By producing artificially-altered synthetic data of the poor-quality inputs comprising real data, a training dataset can be expanded far beyond the availability of real data, improving the efficacy of training over time.

In the preferred embodiment, multilayer, deep CNNs are used for each species to identify an invasive species in a present image with high precision and accuracy. Using the CNNs to detect invasive species, sightings of invasive species will be reported to the Network. Existing datasets are used to train machine learning models. The Bugwood Database maintained by the University of Georgia has been used in prototyping. However, any sufficiently comprehensive data set might be used; such datasets will be apparent to one skilled in the art in light of this disclosure. In this preferred embodiment, the CNNs will tend to improve over time as additional images are captured and stored on the Network displaying indexed species, whether native, invasive, or unknown. For purposes of this invention, the term “images” refers primarily to images of any given indexed species, but in further embodiments may refer to images associated with a species but not directly including the species itself, such as images of the species' tracks, droppings, eggshells, nests, shed skin, or other signs. Yet further refinements of these embodiments may include non-visual data such as the sounds emitted by an indexed species. These variations and embodiments are reviewed analogously to images and are intended to be included in claims for such images and their implementation in the claimed invention.

To minimize unnecessary errors during image classification, a separate CNN model is preferably trained for each of the indexed invasive plant, wildlife, insect, and pathogen categories. In the event there are insufficient training images of sufficient quality, machine learning is preferably enhanced by transfer learning. Transfer learning, a method in which a pre-trained model is repurposed for another task, decreases training time by training a machine on similar objects before training on the desired objects. Transfer learning, however, is only the first step in preparing the training of the preferred visual-recognition embodiment. A next step of decreasing the variance and overfitting problem of the CNNs is to augment existing images by altering rotation, brightness, contrast, vertical shift, horizontal shift, and other parameters in order to generate augmented image copies. These images, being synthetic images, are then added to the genuine images as part of the training set until a desired minimum quantity of images in said training set is reached. This technique can create additional training data until the total number of images exceeds a preferred minimum of two hundred. Lower numbers of training images may be used, and are indeed preferable for certain species with extremely low of available images or other sighting data.

The process may be yet further enhanced by the process of a generative adversarial network 302 developing artificial images of a selected indexed species. In this enhancement, a generative artificial intelligence and a discriminatory artificial intelligence compete. The generative artificial intelligence, being trained on available images of an indexed species, generates one or more synthetic images of said indexed species. The discriminatory artificial intelligence independently makes a determination of whether each synthetic image is genuine or artificial. The generative adversarial network 302 model stacks the discriminator and generator, thereby allowing for the generator's weights to adjust to the discriminator's performance iteratively in this zero-sum competition. After training for many epochs, but preferably for at least five hundred epochs, the generator model may be used to generate realistic synthetic images for each species with less than the desired number of training images. Preferably, at least two hundred total synthetic and genuine images are used in training the machine learning algorithm.

In the preferred embodiment, this process of using the GAN is repeated with the introduction of new instances of species data to further enhance the accuracy of the indexed species identification. In certain embodiments, the machine learning algorithm may be tested against a fixed dataset of indexed species data for accuracy of identification of each indexed species.

In the preferred embodiment, the GAN is trained both to generate synthetic images clearly displaying the indexed species, as well as images mimicking real-world conditions of less-than-ideal quality such as poor lighting, inclement weather, obfuscation by foliage or other objects, and indistinct profiles resulting from suboptimal camera angles or odd animal body positions. This optimizes the model for identifying each indexed species in real-world conditions, rather than optimizing the model for generating synthetic images which would be distinct and clear to a viewer.

In an enhancement to the preferred embodiment, the machine learning algorithm is further trained on a sufficient number of genuine images and/or synthetic images of the indexed species to generate one or more three-dimensional models of the indexed species. The one or more three-dimensional models may further be manipulated at the direction of the user or by the machine learning algorithm and/or GAN to present the species in various states, positions, stages of growth, or conditions. For example, a three-dimensional model of a plant may depict the plant in bloom, while dehydrating, or dry and dead; a three-dimensional model of an animal may depict that animal standing or sitting, juvenile or fully grown, healthy or sick. The machine learning algorithm is then able to extrapolate two-dimensional synthetic images of the three-dimensional model from any angle and in any lighting conditions. Such extrapolated two-dimensional synthetic images further enhance the accuracy of identifying indexed species by the machine learning algorithm as set forth above. Other embodiments of this enhancement to the preferred embodiment may improve upon the three-dimensional model with data other than images, including but not limited to measurement data, LIDAR, RADAR, SONAR, and other types of data known in the art. Yet further embodiments of this enhancement to the preferred embodiment may incorporate three-dimensional models of an indexed species developed by third-parties and downloaded to the invention's memory.

The trained CNNs interact with the selected device on the Network to analyze a present image at the direction of a user. The image, once recognized, is uploaded with location data to the Network. The Network gathers data from all connected devices to produce more up-to-date datasets and more accurate predictions with each iteration. It is preferred that the Network be updated weekly, but other intervals may be employed.

As the Network gathers additional real-world images of each indexed species and accurately identifies each species with its visual-identification machine learning algorithm, that very algorithm can be further updated by training on these gathered images and on artificially enhanced versions of these same images. This yet further increases the accuracy of the system in excess of the accuracy that can be trained using traditional techniques, and even the retraining is faster and more accurate than traditional retraining techniques, as the detection accuracy ensures that newly-added data is a of a very high quality even without significant intervention by users such as data scientists.

The machine learning algorithm comprises a predictive model trained to predict the population and location of invasive species. The preferred predictive model is a LSTM machine learning model; the application of other algorithms or MALs as described herein may be apparent to one skilled in the art in light of this disclosure. The predictive model is configured to generate geospatial predictions of present and future spread of invasive species from existing indexed species datasets. Predictions preferably comprise predictions of a quantity of new predicted cases according to a moving average, namely, a seasonal autoregressive integrated moving average with exogenous regressors. The moving average is continuously recalculated according to seasonality, determined by growth and decline data contained within the appropriate dynamic species model 300, by the time period of the prediction, and by the value of previous predictions after the first prediction. Predictions further preferably comprise geospatial coordinates. Each recorded or predicted location of an instance of an indexed species is assigned an appropriate integer cluster group; such cluster groups allow the predictive model to output geospatial coordinate predictions according to a hierarchical density-based geospatial clustering algorithm. These coordinate predictions are then further recursively utilized to update the predictive model. The predictive model may further preferably incorporate data on local climate and weather, local predation and competition, and other parameters that may be apparent to one skilled in the art in light of this disclosure.

The machine learning algorithm is trained according to a method, the steps of which comprise providing available data to the machine learning algorithm as set forth in the preceding paragraph, receiving output in the form of predictions from the machine learning algorithm, auditing the output, updating the data, and repeating the preceding steps for preferably at least two hundred epochs.

Further contextual parameters may be set by an operator of the Network in embodiments comprising the Network; parameters may be subsequently modified by the Operator, or dynamically adjusted by a machine learning algorithm within the Network itself

Each occurrence for each species is organized in a time series format, from earliest to present. A moving average model is used to predict the number of new invasive species occurrences at given time intervals according to seasonality, rates of growth or decline at certain periods of time, best-matched invasive species' previous growth patterns, and other data as will be apparent to one skilled in the art in light of this disclosure. To better predict the locational movement of various types or “clusters” of invasive species, models of the invasive species' position and mutual reachability distance are compared, according to a selected normalized clustering value; the machine learning model will preferably model each of these as a separate LSTM model. Additional data influencing the predictive model include weather, humidity, temperature, rainfall, and wind speed at selected coordinates; said data is preferably scraped from a selected database. Finally, the moving average of geospatial growth will further comprise parameters for a predation and competition of each indexed species.

The moving average prediction for instances of each indexed species may be displayed by the Network via an output device, preferably as a population density map or spreadsheet. Inclusion of a “heat map” of actual and predicted invasive species presence over a given map of a geographical region is preferred.

Other output may be displayed by the invention in forms known in the art, or which may be apparent to one skilled in the art in light of the present disclosure.

Other embodiments of the present invention may comprise additional sensory inputs in order to better identify and differentiate at-risk, endangered, native, and invasive species. Such sensory inputs may include the sounds emitted by each species, the shape and size of tracks or droppings left by animal species, or the physical symptoms of invasive pathogenic species.

Further embodiments of the present invention may comprise input devices including but not limited to traditional data-collection devices and techniques including drones, field rovers, static wildlife cameras, wearable devices, and other field surveillance systems as will be apparent to one skilled in the art in light of the present disclosure. Non-traditional data collection devices and techniques as input devices are further embodied in software configured to autonomously collect or “scrape” data from databases selected by a user,

Yet further embodiments of the present invention may comprise enhancements to the predictive models accounting for the interaction of several invasive species in parallel. For example, invasive plants may be consumed or otherwise inhibited by the presence of invasive insects which feed on these plants. In other instances, native species may adapt to the presence of some invasive species, but not others. Such embodiments dynamically adjust the parameters for predation and reproduction of invasive species and native species in order to generate more accurate predictions; as with the base invention, these parameters would dynamically adjust future predictions as actual indexed species data is uploaded to the database.

Additional embodiments of the present invention may further comprise parameters for recognizing instances in which actual indexed species data diverges significantly from predicted data to recognize the need for re-training of one or more machine learning algorithms and to do so either automatically or at the direction of a user.

The preferred embodiment is intended to be implemented by means of a mobile application which can be downloaded by any mobile device user to connect to the Network. This embodiment simplifies controlling invasive species and is a significant enhancement in the currently manual Early Detection and Rapid Response (EDRR) Methods. The Network automates and crowdsources the key factors of early detection, quick response, and public awareness in stopping invasive species growth, and is no longer as labor-intensive as current EDRR Methods. Additionally, the identification models used in the application outperform traditional state-of-the-art classification models over time, as the increased availability of new real-world data further enhances the machine learning algorithm. The dynamic system of the application, which constantly updates predictions based on current reports, provides a both novel and sustainable method of combatting invasive species, and unlike current applications, can also automatically identify, detect, and predict invasive species growth. The project is as scalable as the distribution of electronic devices and benefits from the parallel work of crowdsourcing, both in terms of improved datasets for the machine learning algorithm which predicts the spread of invasive species and in terms of the machine learning algorithm which identifies indexed species from visual images and other input.

Other embodiments of the present invention may be apparent to one skilled in the art in light of the present disclosure. Such embodiments are intended to included in the scope of the claims herein.

What is claimed is:

1. A computer-implemented invasive species tracking and prediction model, the model comprising:
A computing device, said computing device comprising at least one processor, at least one memory communicatively coupled to the at least one processor, at least one input device communicatively coupled to the at least one processor, and at least one output device communicatively coupled to the at least one processor;
Computer code stored in said computer, said computer code comprising data and instructions configured to affect the computing device according to at least the following operations:
Store a plurality of dynamic species models, each corresponding to an indexed species, each dynamic species model further comprising an at least one machine learning algorithm and an updateable species dataset, said machine learning algorithm being configured to comprise in part at least an at least one generative adversarial network, a geospatial growth prediction algorithm, and an identifying machine learning algorithm, and each of said updateable species dataset being configured to store at least one instance of one indexed species and at least one corresponding indexed species datum;
By means of the geospatial growth prediction algorithm, generate one or more predictions of the movement and growth of each indexed species according to the dynamic species model;
Display the prediction by means of the at least one output device;
Accept new indexed species data by means of the at least one input device;
By means of the identifying machine learning algorithm, identify which of the plurality of dynamic species models, if any, corresponds to new indexed species data;
Update the updateable species dataset according to the new indexed species data;
Train the machine learning algorithm according to the updateable species dataset;
Select a new indexed species datum, copy said new indexed species datum, alter said new indexed species datum by means of the generative adversarial network, and store the altered said new indexed species datum according to the updateable species dataset;
Perform the operation of iteratively training the at least one machine learning algorithm according to the corresponding indexed species dataset.

2. The model of claim 1, in which the indexed species datum comprises at least an image of said indexed species, in which the altered new species datum comprises at least an altered image of said indexed species, and in which the at least one input device comprises at least one imaging device.

3. The model of claim 2, in which the indexed species datum comprises cumulatively at least two hundred images and altered of said indexed species images.

4. The model of claim 2, in which the generative adversarial network is configured such that the altered image of said indexed species is altered from the corresponding image according to one or more of image brightness, rotation, zoom, focus, vertical shift, horizontal shift, color saturation, or contrast.

5. The model of claim 1, in which the machine learning algorithm further comprises a discriminatory machine learning algorithm, in which the computer code further comprises data and instructions configured to affect the computing device according to at an operation comprising the step of evaluating the altered new indexed species datum, rejecting such altered indexed species datum if not sufficiently in conformity with the indexed species, and accepting the altered indexed species datum if sufficiently in conformity with the indexed species and storing said altered indexed species datum according to the updateable species dataset.

6. A method of using the model of claim 1, in which the method comprises the steps of iteratively training the machine learning algorithm of each dynamic species model according to the indexed species data and altered indexed species data through a plurality of epochs to improve the accuracy of the operation of the machine learning model identifying the indexed species.

7. The method of claim 6, in which the step of iteratively training the machine learning algorithm is performed on a weekly basis.

8. The model of claim 1, in which the computing device is communicatively coupled to an at least one other computing device, in which the computer code further comprises data and instructions to perform the operation of receiving new indexed species data from the at least one input device of the at least one other computing device.

9. The model of claim 8, in which the at least one other computer device comprises a mobile device, and in which the element of being communicatively coupled comprises connection through the Internet.

10. The model of claim 1, in which each indexed species is an invasive species.

11. The model of claim 1, in which the prediction is displayed in a form at least comprising a population density map.

12. The model of claim 1, in which the machine learning model comprises at least a convolutional neural network.

13. The model of claim 1, in which the which the indexed species datum comprises an at least one three-dimensional model of said indexed species.

14. The model of claim 13, in which the at least one three-dimensional model of said indexed species.
